(19) United States
(12) Patent Application Publication
(10) Pub. No.: US 2013/0061919 A1
(43) Pub. Date: Mar. 14, 2013

(54) METHOD OF MANUFACTURING SOLAR CELL ELECTRODE

(71) Applicants: ALAN FREDERICK CARROLL, Raleigh, NC (US); Norihiko Takeda, Kanagawa (JP)

(72) Inventors: ALAN FREDERICK CARROLL, Raleigh, NC (US); Norihiko Takeda, Kanagawa (JP)

(73) Assignee: E I DU PONT NEMOURS AND COMPANY, Wilmington, DE (US)

(21) Appl. No.: 13/415,238

(22) Filed: Mar. 8, 2012

Related U.S. Application Data
(60) Provisional application No. 61/454,133, filed on Mar. 18, 2011.

(51) Int. Cl. H01L 31/18; H01L 31/0224

(52) U.S. Cl. 136/256; 438/98; 257/E31.125

(57) ABSTRACT

A method of manufacturing an n-type electrode comprising the steps of: preparing an N-type base semiconductor substrate, comprising an n-base layer, a p-type emitter on the n-base layer, a first passivation layer on the p-type emitter, and a second passivation layer on the n-base layer; applying a conductive paste onto the second passivation layer on the n-base layer, wherein the conductive paste comprises, (i) 100 parts by weight of a conductive powder, (ii) 0.1 to 10 parts by weight of an aluminum powder with particle diameter of 2 to 12 μm, (iii) 3.5 to 25 parts by weight of a glass frit, and (iv) an organic medium; and firing the conductive paste at temperature of 910° C. or lower.

### CROSS-REFERENCE TO RELATED APPLICATION

This application claims the benefit of U.S. Provisional Application No. 61/45413, filed Mar. 18, 2011.

### FIELD OF THE INVENTION

This invention relates to an N-type base solar cell, more specifically a method of manufacturing an n-type electrode thereof.

### BACKGROUND OF THE INVENTION

A solar cell electrode is required to have low electrical resistance to improve conversion efficiency (Eff) of a solar cell. Especially in N-type base solar cells, solar cell electrodes sometimes insufficiently contact a semiconductor to render Eff lower. US20100059106 discloses that a conductive paste to form an n-type electrode of an N-type base solar cell could contain metal powders such as Ag, Au, Pt, Al, Cu, Ni, Pd.

### BRIEF SUMMARY OF THE INVENTION

An objective of the present invention is to provide a method of manufacturing an n-type electrode which has lower contact resistance to an n-base layer.

In an aspect of this present invention, a method of manufacturing an n-type electrode comprising the steps of: preparing an N-type base semiconductor substrate, comprising an n-base layer, a p-type emitter on the n-base layer, a first passivation layer on the n-base layer, and a second passivation layer on the p-type emitter; applying a conductive paste onto the first passivation layer on the n-base layer, wherein the conductive paste comprises, (i) 100 parts by weight of a conductive powder, (ii) 0.1 to 10 parts by weight of an aluminum powder with particle diameter of 2 to 12 μm, (iii) 3.5 to 25 parts by weight of a glass frit, and (iv) an organic medium; and firing the conductive paste at temperature of 910° C. or lower.

In another aspect of this present invention, an N-type base solar cell comprising the n-type electrode formed by the method above.

An n-type electrode can obtain low contact resistance with an n-base layer of a semiconductor substrate.

### BRIEF DESCRIPTION OF THE DRAWINGS

FIG. 1A to 1F are drawings for explaining a production process for manufacturing an n-type electrode of an N-type base solar cell.

FIG. 2 is a result of Example where aluminum powder content was examined.

FIG. 3 is a result of Example where particle diameter of the aluminum powder was examined.

FIG. 4 is a result of Example where glass frit content was examined.

FIG. 5 is a result of Example where firing temperature was examined.

### DETAILED DESCRIPTION OF THE INVENTION

The present invention relates to a method of manufacturing an n-type electrode. The n-type electrode is an electrode formed, through a passivation layer, on an n-base layer of an N-type base semiconductor substrate. The N-type base semiconductor substrate here comprises a p-type emitter, an n-base layer and passivation layers. The p-type emitter is formed at one side of the N-type base semiconductor substrate. The passivation layers are formed on the p-type emitter and the n-base layer respectively.

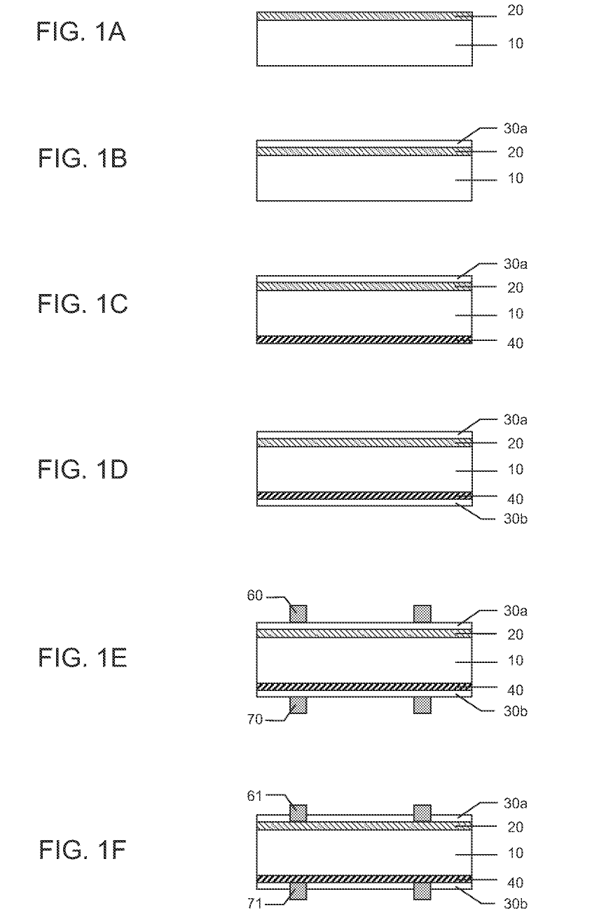

In an embodiment, the N-type base semiconductor substrate comprises a first passivation layer 30a, a p-type emitter 20, n-base layer 10, optionally n⁺-layer 40, and a second passivation layer 30b formed in this order as illustrated in FIG. 1D. In an embodiment, the N-type base semiconductor comprises a p-type electrode 61, a first passivation layer 30a, a p-type emitter 20, n-base layer 10, optionally n⁺-layer 40, a second passivation layer 30b, and a n-type electrode 71 formed in this order as illustrated in FIG. 1F, where the p-type electrode 61 passes through the first passivation layer 30a to have an electric contact with the p-type emitter 20 and the n-type electrode 71 passes through the second passivation layer 30b to have an electric contact with the n-base layer 10 or n⁺-layer 40.

A p-type emitter can be defined as a semiconductor layer containing an impurity called acceptor dopant where the acceptor dopant introduces deficiency of valence electrons in the semiconductor element. In the p-type emitter, the acceptor dopant takes in free electrons from semiconductor element and consequently positively charged holes are generated in the valence band.

An n-base layer can be defined as a semiconductor layer containing an impurity called donor dopant where the donor dopant introduces extra valence electrons in the semiconductor element. In the n-base layer, free electrons are generated from the donor dopant in the conduction band.

By adding an impurity to an intrinsic semiconductor as above, electrical conductivity can be varied not only by the number of impurity atoms but also, by the type of impurity atom and the changes can be a thousand fold and a million fold.

Embodiments of the present invention are explained below with reference to the drawings in FIG. 1. The embodiments given below are only examples, and appropriate design changes are possible for those skilled in the art.

In one embodiment is a method of manufacturing an n-type electrode.

FIG. 1A shows a part of an N-type base semiconductor substrate comprising an n-base layer 10 and a p-type emitter 20. The n-base layer 10 can be formed by being doped with a donor impurity such as phosphorus. The p-type emitter 20 can be formed, for example, by thermal diffusion of an acceptor dopant into an N-type base semiconductor substrate. In silicon semiconductors, the acceptor dopant can be boron (B). The thickness of the p-type emitter can be, for example, 0.1 to 10% of the N-type base semiconductor substrate thickness.

As shown in FIG. 1B, a first passivation layer 30a can be formed on the p-type emitter 20. The first passivation layer 30a can be 10 to 2000 Å thick. Silicon nitride (SiNₓ), silicon carbide (SiCₓ), Titanium oxide (TiO₂), Aluminum oxide (Al₂O₃), Silicon oxide (SiOₓ), Indium Tin Oxide (ITO), or a mixture thereof can be used as a material of the first passivation layer 30a. The first passivation layer 30a can be formed by, for example, plasma enhanced chemical vapor deposition (PECVD) of these materials.

In an embodiment, as shown in FIG. 1C, an n⁺-layer 40 can be formed at the other side of the p-type emitter 20, although it is not essential. The n⁺-layer 40 contains the donor impurity with higher concentration than that in the n-base layer 10. For example, the n⁺-layer can be formed by thermal diffusion of phosphorus in silicon semiconductors. By forming n⁺-layer, the recombination of electrons and holes at the border of n-base layer and n⁺-layer can be reduced. When the n⁺-layer 40 is formed, the N-type base semiconductor substrate comprises the n⁺-layer between the n-base layer 10 and a passivation layer 30 which is formed in the next step.

As shown in FIG. 1D, a second passivation layer 30b is formed on the n⁺-layer 40. The N-type base semiconductor substrate comprising the n-base layer 10, the p-type emitter 20, the first passivation layer 30a and the second passivation layer 30b can be obtained here. The material and forming method of the second passivation layer 30b can be the same as the other one described above. However, the second passivation layer 30b can be different from that on the p-type emitter in terms of its forming material or its forming method.

When the passivation layer(s) 30a and/or 30b is illuminated by sunlight in the operation of a solar cell, the passivation layer(s) 30a and/or 30b reduces the carrier recombination and reduces optical reflection losses so that it is also called an anti-reflection coating (“ARC”). Both sides of the n-base layer 10 and the p-type emitter 20 can be a light receiving side in the operation.

As shown in FIG. 1E, a conductive paste 70 for forming an n-type electrode is applied onto the second passivation layer 30b. The conductive paste 70 for forming an n-type electrode is described more in detail below. A conductive paste 60 for forming a p-type electrode is also applied onto the first passivation layer 30a. When applying the conductive paste, screen printing can be used.

In an embodiment, the conductive paste 60 on the first passivation layer 30a can be different in composition from the conductive paste 70 on the n-base layer 40. The composition of these conductive pastes can be respectively adjusted depending on, for example, material or thickness of the passivation layers 30a and 30b.

In another embodiment, the conductive paste 60 and the conductive paste 70 can be same in composition. When both of the conductive pastes 60 and 70 are same, the manufacturing process can be simpler to result in reducing the production cost.

The conductive paste 60 and 70 at the both side can be dried for 10 seconds to 10 minutes at 150° C.

Firing the conductive pastes is then carried out. As shown FIG. 1F, the conductive pastes 60 and 70 fire through the passivation layers 30a and 30b during the firing so that a p-type electrode 61 and an n-type electrode 71 can have good electrical connections with the p-type emitter 20, and the n⁺-layer 40 respectively. When the connections between these electrodes and semiconductor are improved, the electrical property of a solar cell will also be improved.

An infrared furnace can be used for the firing process. In an embodiment, the firing peak temperature can be in the range of 450° C. to 1000° C., in another embodiment, 500° C. to 950° C., in another embodiment, 700° C. to 800° C. In an embodiment, the firing time from an entrance to an exit of a furnace can be from 30 seconds to 5 minutes, in another embodiment 40 seconds to 3 minutes. In another embodiment, the firing profile can be 10 to 60 seconds at over 400° C. and 2 to 10 seconds at over 600° C. The firing temperature is measured at the upper surface of the semiconductor substrate. When the firing temperature and time are within the range, less damage can occur to the semiconductor substrate during firing.

When actually operated, the solar cell can be installed with the n-base layer located at the backside which is the opposite side of the light receiving side of a solar cell. The solar cell can be also installed with the p-type emitter located at the backside which is the opposite side of the light receiving side of a solar cell.

Next, a conductive paste 70 that is used in the method of manufacturing described above is explained in detail below. The conductive paste 70 to form an n-type electrode 71 comprises at least a conductive powder, aluminum powder, a glass frit and an organic medium.

### Conducting Powder

Conductive powder is a metal powder to transport electrical current in an electrode. In an embodiment, the conductive powder can be selected from the group consisting of silver (Ag), copper (Cu), nickel (Ni) powder and a mixture thereof. The conductive powder can be also an alloy of Ag, Cu, Ni. Using such conductive powder with relatively high electrical conductivity, the resistive power loss of a solar cell can be minimized. In another embodiment, the conductive powder can be Ag powder. Ag powder can be difficult to oxidize during firing in the air to keep conductivity high.

In an embodiment, the conductive powder can be 80 to 98.5 weight percent (wt %), in another embodiment 83 to 95 wt %, in another embodiment 85 to 90 wt %, based on the total weight of the conductive powder, aluminum powder and glass frit. The conductive powder with such amount in the conductive paste can retain sufficient conductivity for solar cell applications.

In an embodiment, the conductive powder can be flaky or spherical in shape.

There are no special restrictions on the particle diameter of the conductive powder from a viewpoint of technological effectiveness when used as typical electrically conducting paste. However, since the particle diameter affects the sintering characteristics of conductive powder, for example, large silver particles are sintered more slowly than silver particles of small particle diameter. For this reason, in an embodiment, the particle diameter can be 0.1 to 10 μm, in another embodiment, 1 to 7 μm, in another embodiment, 1.5 to 4 μm. In another embodiment, the conductive powder can be a mixture of two or more of conductive powder with different particle diameter.

The particle diameter (D50) is obtained by measuring the distribution of the particle diameters by using a laser diffraction scattering method and can be defined as D50. Microtrac model X-100 is an example of the commercially-available devices.

In an embodiment, the conductive powder can be of ordinary high purity of 99% or higher. However, depending on the electrical requirements of the electrode pattern, less pure silver can also be used.

### Aluminum Powder

Aluminum (Al) powder is a metal powder containing at least Al. The purity of the Al powder can be 99% or higher. The Al powder in the conductive paste is 0.1 to 10 parts by weight based on 100 parts by weight of the conductive powder. By adding Al powder to the conductive paste, electrical property of the N-type base solar cell can be improved as shown in Example below. The Al powder can be 0.2 to 8 parts by weight in another embodiment, 0.3 to 5.8 parts by weight in another embodiment, and 1.0 to 4 parts by weight in another embodiment.

The particle diameter (D50) of the aluminum powder is 2 to 12 μm. With such particle diameter of aluminum powder, the n-type electrode can have better contact with n-base layer as shown in examples below. In another embodiment, the particle diameter of Al 3 to 11 μm, and in still another embodiment 5 to 10 μm. To measure the particle diameter (D50) of the Al powder, the same method as used for the conductive powder can be applied.

In an embodiment, the Al powder can be flaky, nodular, or spherical in shape. In another embodiment, the Al powder can be spherical. Nodular powder is irregular particles with knotted, rounded shapes.

### Glass Frit

Glass frits used in the conductive pastes described herein etch through the passivation layer during firing process and facilitate binding of the electrode to the semiconductor substrate and may also promote sintering of the conductive powder.

The glass frit is 3.5 to 25 parts by weight based on 100 parts by weight of the conductive powder. The conductive paste containing the amount of the glass frit can form the n-type electrode with sufficient contact with the semiconductor substrate as shown in Example below. In another embodiment, 4 to 20 parts by weight, in another embodiment, 6 to 16 parts by weight, based on 100 parts by weight of the conductive powder.

Glass frit is described herein as including percentages of certain components. Specifically, the percentages are the amount of the components used in the starting material that was subsequently processed to form a glass frit. In other words, the glass frit contains certain components, and the percentages of those components are expressed as a percentage of the corresponding oxide form. As recognized by one of skill in the art in glass chemistry, a certain portion of volatile species may be released during the process of making the glass.

In an embodiment, the glass frit comprises one or more oxide selected from a group consisting of lead oxide (PbO), silicon oxide (SiO₂) and boron oxide (B₂O₃).

In an embodiment, lead oxide (PbO) can be 44 to 80 mol %, in another embodiment 50 to 73 mol %, in another embodiment 55 to 68 mol %, based on the total molar fraction of each component in the glass frit.

In an embodiment, silicon oxide (SiO₂) can be 0.5 to 40 mol %, in another embodiment 1 to 33 mol %, in another embodiment, 1.3 to 25 mol %, based on the total molar fraction of each component in the glass frit.

In an embodiment, boron oxide (B₂O₃) can be 15 to 48 mol %, in another embodiment 20 to 43 mol %, in another embodiment, 22 to 40 mol %, based on the total molar fraction of each component in the glass frit.

In an embodiment, the glass frit can further comprise aluminum oxide (Al₂O₃). In an embodiment, Al₂O₃ can be 0.01 to 6 mol %, in another embodiment 0.09 to 4.8 mol %, in another embodiment 0.5 to 3 mol %, based on the total molar fraction of each component in the glass frit.

In another embodiment, the softening point of the glass frits can be 300 to 600° C., in another embodiment 310 to 500° C., in another embodiment 320 to 400° C.

In this specification, “softening point” is determined by differential thermal analysis (DTA). To determine the glass softening point by DTA, sample glass is ground and is introduced with a reference material into a furnace to be heated at a constant rate of 5 to 20° C. per minute. The difference in temperature between the two is detected to investigate the evolution and absorption of heat from the material. In general, the first evolution peak is at the glass transition temperature (Tg), the second evolution peak is at the glass softening point (Ts), the third evolution peak is at the crystallization point. When a glass frit is a non-crystalline glass, the crystallization point would not appear in DTA.

The glass frit can be prepared by methods well known in the art. For example, the glass component can be prepared by mixing and melting raw materials such as oxides, hydroxides, carbonates, making into a cullet by quenching, followed by mechanical pulverization (wet or dry milling). Thereafter, if needed, classification is carried out to the desired particle size.

### Organic Medium

Organic medium allows constituents of the conductive powder, the aluminum powder and the glass frit to be dispersed in the form of a viscous composition called “paste”, having suitable consistency and rheology for applying to a substrate by a method such as screen printing. The organic medium can be an organic resin or a mixture of an organic resin and an organic solvent.

The organic medium can be, for example, a pine oil solution or an ethylene glycol monobutyl ether monoacetate solution of polymethacrylate, or an ethylene glycol monobutyl ether monoacetate solution of ethyl cellulose, a terpineol solution of ethyl cellulose, or a texanol solution of ethyl cellulose.

In an embodiment, the organic medium can be a terpineol solution of ethyl cellulose where the ethyl cellulose content is 5 wt % to 50 wt % based on the total weight of the organic medium.

A solvent can be used as a viscosity-adjusting agent. The solvent amount can be adjustable for desired viscosity. For example, the conductive paste viscosity can be 50 to 350 Pascal per second (Pa·s) when the conductive paste is applied by screen printing. The viscosity here is measured at 10 rpm and 25° C. with a Brookfield HBT viscometer with #14 spindle. The viscosity changes dependent upon the application method so that it can be suitably determined by a person with ordinary skill in the art.

The content of the organic medium can be 5 to 50 wt % based on the total weight of the conductive paste.

The organic medium can be burned off during the firing step so that the n-type electrode ideally contains no organic residue. However, actually, a certain amount of residue can be allowable as long as does not degrade the electrical property of the n-type electrode.

### Additives

Additives such as a thickener, a stabilizer, a dispersant, a viscosity modifier or a surfactant can be added to a conductive paste as the need arises. The amount of the additive depends on the desired characteristics of the resulting conductive paste and can be chosen by people in the industry. Multiple kinds of the additives can be also added to the conductive paste.

Although components of the conductive paste were described above, the conductive paste can contain an impurity coming from raw materials or contained during manufacturing process. However, the presence of the impurity would be allowed (defined as benign) as long as it insignificantly altered properties of the conductive paste. For example, the p-type electrode manufactured with the conductive paste can achieve sufficient electric property described herein, even if the conductive paste includes a benign impurity.

### Example

The present invention is illustrated by, but is not limited to, the following examples.

### Preparation of Conductive Paste

Conductive pastes to form n-type electrodes were prepared with the following procedure by using the following materials. The solid material amounts are in Table 1.

Conductive powder: Spherical Ag powder with particle diameter (D50) of 3 μm was used.

Aluminum (Al) powder: Spherical Al powder with particle diameter (D50) of 3.1 μm was used.

Glass frit: Glass frit containing 60.0 mol % of PbO, 2.0 mol % of SiO₂, 2.0 mol % of Al₂O₃, 36.0 mol % of B₂O₃ was used. The softening point determined by DTA was 378° C.

Organic medium: A mixture of texanol solution and ethyl cellulose was used.

Additive: a viscosity modifier was used.

TABLE 1

| | Ag powder | Glass frit | Al powder |
|---|---|---|---|
| Paste No. | (parts by weight) | (parts by weight) | (parts by weight) |
| 1 | 100 | 8.70 | 0.00 |
| 2 | 100 | 8.71 | 0.11 |
| 3 | 100 | 8.71 | 0.22 |
| 4 | 100 | 8.74 | 0.55 |
| 5 | 100 | 8.86 | 1.88 |
| 6 | 100 | 9.20 | 5.75 |
| 7 | 100 | 9.52 | 9.52 |

The organic medium was added in the event the viscosity modifier was added, and the composition was mixed for 15 minutes. To enable dispersion of a small amount of the Al powder evenly in the conductive paste, the Ag powder and the Al powder were dispersed in the organic medium separately to mix together afterward. First, the Al powder was dispersed in some of the organic medium and mixed for 15 minutes to form the Al paste. The glass frit was dispersed in the rest of the organic medium and mixed for 15 minutes and then Ag powder was incrementally added to form the Ag paste. Then, the mixture was repeatedly passed through a 3-roll mill at progressively increasing pressures from 0 to 400 psi. The gap of the rolls was adjusted to 1 mil. Then the Ag paste and the Al paste were mixed together to form the conductive paste. Finally the additional organic medium or thinners were mixed to have desired viscosity of the paste. The organic medium in the conductive paste was 11 to 12 wt % based on the total weight of the conductive paste.

The viscosity as measured at 10 rpm and 25° C. with a Brookfield HBT viscometer with #14 spindle was 260 Pa·s. The degree of dispersion as measured by fineness of grind was 20/10 or less.

### Manufacture of Test Pieces

The conductive paste obtained as the above was screen printed onto a silicon nitride layer with 70 nm average thickness that was formed on an n-base layer of a silicon substrate. The printed conductive paste was dried at 150° C. for 5 min in a convection oven.

Electrodes were then obtained by firing the printed conductive paste with the p-type emitter side facing up in an IR heating type of belt furnace (CF-7210B, Despatch industry) at peak temperature setting with 845° C. The temperature on the upper surface of the silicon wafer corresponded to approximately 110° C. lower than the furnace set peak temperature. Firing time from furnace entrance to exit was 80 seconds. The firing condition was less than or equal to the furnace set temperature, 400 to 600° C. for 10 to 15 seconds, and over 600° C. for 5 to 10 seconds. The belt speed of the furnace was 550 cpm.

Fifteen line electrodes with 20 mm long, 0.22 mm wide in average, and 25 μm thick in average were formed on the silicon substrate sized of 20 mm width and 30 mm length. The interval between the center of the electrodes was 2 mm.

### Test Procedure

The contact resistance (R_{c}) between the electrodes and the n-type silicon layer measured using an apparatus equipped with a source meter (Keithley Instruments model 2400) and set of current and voltage probes controlled by PC. A transfer length method (TLM) based technique was used to obtain one value of R_{c} from neighboring four lines as follows. TLM method can be referred to the literature, “Semiconductor Material and Device Characterization” 3rd Ed. D. K. Schroder, Wiley-Interscience, New Jersey, 2006.

The set of measurement consists of the following two steps: (1) measure voltage between the inner two lines while flowing a direct current through them, which gives a sum of 2×R_{c} and Rₛₕₑₑₜ where R_{c} is average contact resistance of the inner two contacts and Rₛₕₑₑₜ is sheet resistance of the substrate between the inner two contacts; (2) measure voltage between the inner two lines while flowing a direct current between the outer two contacts, which gives Rₛₕₑₑₜ between the inner two contacts. The difference between two data divided by two essentially gives average R_{c} of the inner two contacts. A typical direct current used for R_{c} measurements was 10 mA.

The specific contact resistance (sRc) was calculated by multiplying measured R, by contact area, sR_{c}=R_{c}×d×W, where d represents line width and W represents line length.

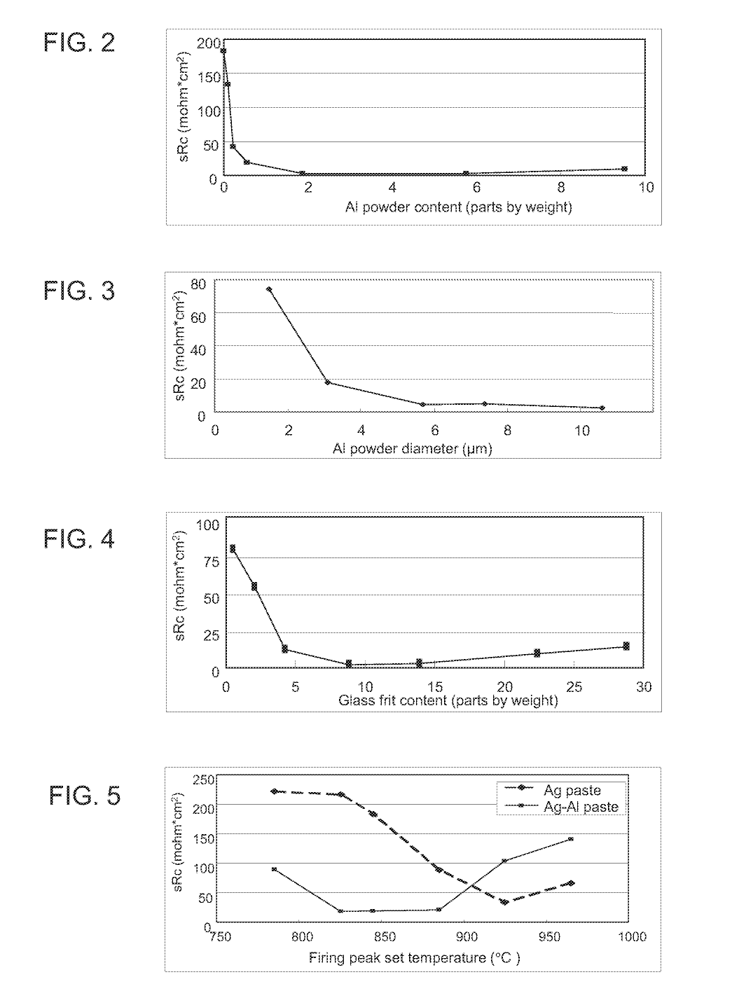

When the Ag paste with no Al powder addition was used to form an n-type electrode fired at 845° C. peak set temperature, a high average sRc of 182.9 mohm·cm² was obtained. When 0.6 parts by weight or more of Al powder was added to the paste, the average sRc for the corresponding n-type electrode drastically dropped to 18.9 mohm·cm² or even lower as shown in FIG. 2.

Next, the effect of the diameter of the Al powder was examined. The n-type electrodes were formed in the same manner with the paste No. 4 above except for using a different particle diameter (D50) of 1.5, 3.1, 5.7, 7.4 or 10.6 μm, respectively. As a result, sRc sharply fell down to 20 mohm·cm² or even lower when using Al powder with diameter of 3.1 μm or larger as shown in FIG. 3.

Next, the effect of the glass frit amount was examined. The n-type electrodes were formed in the same manner of examining Al powder content above except for using a different amount of the glass frit as shown in Table 2 and a different glass frit composition which was 60.0 mol % of PbO, 12.5 mol % of SiO₂, 1.0 mol % of Al₂O₃, 26.5 mol % of B₂O₃. The softening point determined by DTA was 383° C. As a result, sRc dramatically decrease from 81 mohm·cm² of paste No. 8 to 2 mohm·cm² of paste No. 12 by adding the glass frit of 8.9 parts by weight as shown in FIG. 4. sRc of all n-type electrodes of paste No. 9 to 14 were lower than that of paste No. 8.

TABLE 2

| | Ag powder | Glass frit | Al powder |
|---|---|---|---|
| Paste No. | (parts by weight) | (parts by weight) | (parts by weight) |
| 8 | 100 | 0.5 | 1.7 |
| 9 | 100 | 2.1 | 1.8 |
| 10 | 100 | 4.2 | 1.8 |
| 11 | 100 | 8.9 | 1.9 |
| 12 | 100 | 13.9 | 2.0 |
| 13 | 100 | 22.4 | 2.1 |
| 14 | 100 | 28.8 | 2.2 |

Next, the effect of the firing temperature was examined. The n-type electrodes were formed in the same manner of examining Al powder content using paste No. 4 for Ag/Al paste and No. 1 for a comparative Ag paste above except for using a different firing peak temperature with 785, 825, 845, 885, 925, and 965° C., respectively. As a result, sRc obtained for the Ag/Al paste was lower than that for the Ag paste at the firing peak set temperature about 910° C. or lower as shown in FIG. 5. Accordingly, the Ag/Al paste enables contacting to n-type base of solar cells with low contact resistance at a significantly lower firing temperature than the Ag paste. This is beneficial for forming p-type electrode and n-type electrode by co-firing process where relatively lower firing temperature is desired to avoid shunting which degrades solar cell performances.

What is claimed is:

1. A method of manufacturing an n-type electrode comprising the steps of:
preparing an N-type base semiconductor substrate, comprising an n-base layer, a p-type emitter on the n-base layer, a first passivation layer on the p-type emitter, and a second passivation layer on the n-base layer;
applying a conductive paste onto the second passivation layer on the n-base layer, wherein the conductive paste comprises,
(i) 100 parts by weight of a conductive powder,
(ii) 0.1 to 10 parts by weight of an aluminum powder with particle diameter of 2 to 12 μm,
(iii) 3.5 to 25 parts by weight of a glass frit, and
(iv) an organic medium; and
firing the conductive paste at temperature of 910° C. or lower.

2. The method of manufacturing an n-type electrode of claim 1, wherein the glass frit comprises lead oxide (PbO), silicon oxide (SiO₂) and boron oxide (B₂O₃).

3. The method of manufacturing an n-type electrode of claim 1, wherein the softening point of the glass frit is 300 to 600° C.

4. The method of manufacturing an n-type electrode of claim 1, wherein the conductive powder is 80 to 98.5 weight percent (wt %) based on the total weight of the conductive powder, the aluminum powder and the glass frit.

5. The method of manufacturing an n-type electrode of claim 1, wherein firing time is 30 seconds to 5 minutes.

6. The method of manufacturing an n-type electrode of claim 1, wherein the N-type base semiconductor substrate further comprises an n⁺-layer between the n-base layer and the second passivation layer.

7. The method of manufacturing an n-type electrode of claim 1, wherein the conductive powder is selected from a group consisting of silver, copper, nickel and a mixtures thereof.

8. A N-type base solar cell comprising the n-type electrode formed by the method of claim 1.
